(19) United States
(12) Patent Application Publication
(10) Pub. No.: US 2009/0057917 A1
(43) Pub. Date: Mar. 5, 2009

(54) SEMICONDUCTOR DEVICE

(75) Inventor: Eiji Takaike, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/199,291

(22) Filed: Aug. 27, 2008

(30) Foreign Application Priority Data
Aug. 29, 2007 (JP) 2007-222918

(51) Int. Cl. H01L 23/50; H01L 21/60

(52) U.S. Cl. 257/777; 438/108; 257/E23.079; 257/E21.506

(57) ABSTRACT

There is provided a semiconductor device. The semiconductor device includes: a board, a first semiconductor chip and a second semiconductor chip. The first semiconductor chip has a first front face, a first back face, and first external connection terminals provided on the first front face. The first semiconductor chip is mounted on the board via the first external connection terminals by flip-chip bonding. The second semiconductor chip has a second front face, a second back face, and second external connection terminals. The second semiconductor chip is mounted on the first semiconductor chip. The second front face has a contact region contacting the first back face of the first semiconductor chip. The second external connection terminals are provided on the second front face except the contact region. The second semiconductor chip is mounted on the board via the second external connection terminals by flip-chip bonding.

This application is based on and claims priority from Japanese Patent Application No. 2007-222918, filed on Aug. 29, 2007, the entire contents of which are incorporated by reference herein.

### BACKGROUND

1. Technical Field

The present disclosure relates to a semiconductor device, and more particularly to a semiconductor device in which a semiconductor chip having a rewiring bonded to an external connection terminal is stacked on a board.

2. Related Art

With an increase in high-density of a semiconductor device, there is provided semiconductor devices with higher density and integration on which a plurality of semiconductor chips are stacked. For example, JP-A-2005-268533 discloses a semiconductor device in which semiconductor chips are stacked. According to the semiconductor device, two semiconductor chips are stacked on a lead frame or a board while being offset from each other. The respective semiconductor chips are face-up bonded, and the respective semiconductor chips and the board are electrically connected to each other by wire bonding.

However, when the semiconductor chips and the board are electrically connected together by use of the wires, impedance is caused to increase because of the wires being narrow, and thus it is very hard to achieve a high-speed semiconductor chip. Further, since an area where a wire loop is to be formed must be provided in the semiconductor device, there is a problem in that a size of the semiconductor device is increased.

Accordingly, mounting a semiconductor chip on a board by flip-chip bonding instead of by wire bonding is conceivable. Flip-chip bonding is a technique for forming bumps on a front face of the semiconductor chip and face-down bonding the semiconductor chip to the board by the bumps. The flip-chip bonding technique enables a reduction in impedance when compared with the wire bonding technique and can achieve a high-speed semiconductor chip.

FIGS. 1A to 1D show semiconductor chips to be flip-chip bonded according to the related art. A semiconductor chip 1A shown in FIG. 1A has a structure in which bumps 3 are provided in a grid pattern on a front face 2. In semiconductor chips 1B to 1D shown in FIGS. 1B to 1D, bump nonformation areas 4A to 4D where no bumps 3 are provided are formed in a given area of the front face 2. Arrangement positions for the related-art bump nonformation areas 4A to 4D are selected as positions where, when the semiconductor chips 1B to 1D are mounted on the board, arrangement areas for the bumps 3 become symmetrical about the center position of the front face 2 such that the semiconductor chips are stably mounted.

However, the respective semiconductor chips 1A to 1D shown in FIGS. 1A to 1D are not based on the assumption that the semiconductor chips will be mounted on the board in a stacked manner. Thus, mounting efficiency is low. Specifically, when an attempt is made to mount a plurality of semiconductor chips 7A and 7B (two in an illustrated example) on the board 6 as shown in FIG. 2, there is possibility that the semiconductor chips 7A and 7B cannot be mounted on the board 6 of a desired area.

Moreover, when an attempt is made to merely stack the semiconductor chips 1A to 1D shown in FIGS. 1A to 1D on a board 6 by flip-chip bonding, a bump 8A of the semiconductor chip 7A located at a higher position goes up onto the back face of the semiconductor chip 7B located at a lower position as shown in FIG. 3. Therefore, it is very hard to electrically connect the semiconductor chips with each other.

Accordingly, JP-A-2005-183934 describes a semiconductor device in which one of semiconductor chips to be stacked is connected to a board by flip-chip bonding technique and the other semiconductor chip is connected to the board by wire bonding technique.

As described in JP-A-2005-183934, in the structure in which both the flip-chip bonding technique and the wire bonding technique are concurrently used, it is possible to enhance miniaturization and a reduction in thickness, and to improve an electrical characteristics as compared with the structure where all semiconductor chips to be stacked are connected to a board by wire bonding technique.

However, one of the semiconductor chips requires a space in a semiconductor device where a wire loop is to be formed. This leads to an increase in the size of the semiconductor device. Further, there is still a problem in that the wire-bonded semiconductor chip cannot meet a demand for speed-up.

### SUMMARY

Exemplary embodiments of the present invention address the above disadvantages and other disadvantages not described above. However, the present invention is not required to overcome the disadvantages described above, and thus, an exemplary embodiment of the present invention may not overcome any of the problems described above.

According to one or more aspects of the present invention, there is provided a semiconductor device. The semiconductor device includes: a board; a first semiconductor chip having a first front face, a first back face, and first external connection terminals provided on the first front face, the first semiconductor chip being mounted on the board via the first external connection terminals by flip-chip bonding; and a second semiconductor chip having a second front face, a second back face, and second external connection terminals and being mounted on the first semiconductor chip, the second front face having a contact region contacting the first back face of the first semiconductor chip, the second external connection terminals being provided on the second front face except the contact region, the second semiconductor chip being mounted on the board via the second external connection terminals by flip-chip bonding.

According to one or more aspects of the present invention, an area of the contact region accounts for 25% to 50% of an area of the second front face.

According to one or more aspects of the present invention, the second external connection includes a signal external terminal and a power/ground external terminal. The signal external connection terminal is provided near the contact region, and the power/ground external terminal is provided outside the signal external connection terminal.

According to one or more aspects of the present invention, the contact region is formed into a rectangular shape or a triangular shape, and at least two sides of outer peripheral sides of the contact region correspond to outer edges of the second front face.

According to one or more aspects of the present invention, the first semiconductor chip and the second semiconductor chip are formed into the same shape.

According to one or more aspects of the present invention, there is provided a semiconductor device. The semiconductor device includes: a board; a first semiconductor chip having a first front face, a first back face, and first external connection terminals provided on the first front face, the first semiconductor chip being mounted on the board via the first external connection terminals by flip-chip bonding; and four second semiconductor chips each having a second front face, a second back face, and second external connection terminals and being mounted on the first semiconductor chip, the second front face having a contact region contacting the first back face of the first semiconductor chip, the second external connection terminals being provided on the second front face except the contact region, the second semiconductor chip being mounted on the board via the second external connection terminals by flip-chip bonding. Each of the contact regions accounts for 25% of the second front face.

According to one or more aspects of the present invention, there is provided a method of manufacturing a semiconductor device. The method includes the successive steps of: (a) providing a board; (b) mounting a first semiconductor chip on which first external connection terminals are provided, on the board via the first external connection terminals by flip-chip bonding; and (c) mounting a second semiconductor chip on which second external connection terminals are provided, on the board via the second external connection terminals by flip-chip bonding, while the second semiconductor chip being directly mounted on the first semiconductor chip.

According to the present invention, as compared with a configuration in which first and second semiconductor chips are two-dimensionally mounted on a board, mounting efficiency of semiconductor chips on a board can be enhanced, and design flexibility of the semiconductor device can be ensured. Moreover, the first and second semiconductor chips are flip-chip bonded to the board, and hence an attempt can be made to reduce impedance as compared with the case where semiconductor chips are connected by means of wires. Consequently, it is possible to achieve a high-speed semiconductor chip.

Other aspects and advantages of the present invention will be apparent from the following description, the drawings, and the claims.

### BRIEF DESCRIPTION OF THE DRAWINGS

The above and other aspects, features and advantages of the present invention will be more apparent from the following more particular description thereof, presented in conjunction with the following drawings wherein:

FIGS. 1A to 1D are views showing front faces of respective types of semiconductor chips in related-art multilayer semiconductor devices;

FIG. 2 is a view (#1) to describe a drawback in the related-art semiconductor device;

FIG. 3 is a view (#2) to describe the drawback in the related-art semiconductor device;

FIG. 4 is a perspective view of a semiconductor device according to an embodiment of the present invention;

FIG. 5 is a cross-sectional view taken along line V-V shown in FIG. 4;

FIG. 6 is an exploded perspective view to describe a stacked state of a first semiconductor chip and a second semiconductor chip;

FIG. 7 is a perspective view showing the second semiconductor chip in an enlarged manner;

FIG. 8 is a cross-sectional view to describe rewiring of the second semiconductor chip; and

FIGS. 9A to 9C are views to describe another embodiment of the second semiconductor chip.

### DETAILED DESCRIPTION OF EXEMPLARY EMBODIMENTS OF THE PRESENT INVENTION

Exemplary embodiments of the present invention will be described with reference to the drawings hereinafter.

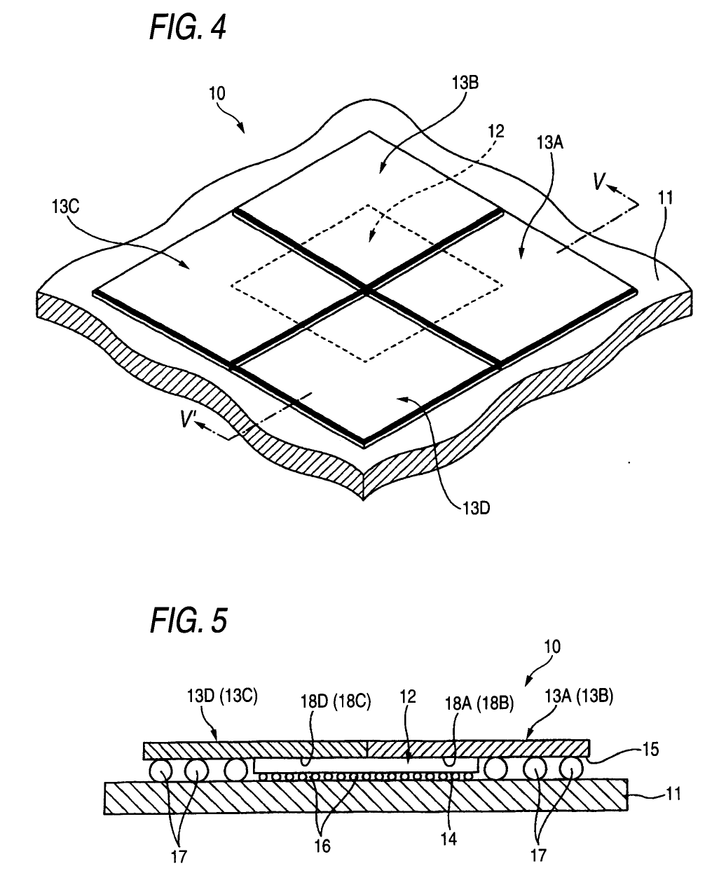

FIGS. 4 and 5 show a semiconductor device 10 according to an exemplary embodiment of the present invention. FIG. 4 is a perspective view of the semiconductor device 10. FIG. 5 is a cross-sectional view taken along line V-V shown in FIG. 4.

The semiconductor device 10 includes a board 11, a first semiconductor chip 12, and a plurality of second semiconductor chips 13A to 13D. The board 11 acts as a mother board on which the respective semiconductor chips 12 and 13A to 13D are to be mounted. The type of the board 11 is not particularly limited to exemplary embodiments, and various types of boards, such as a printed circuit board and a ceramic board, can be used. In the present embodiment, a multilayer printed wiring board is used.

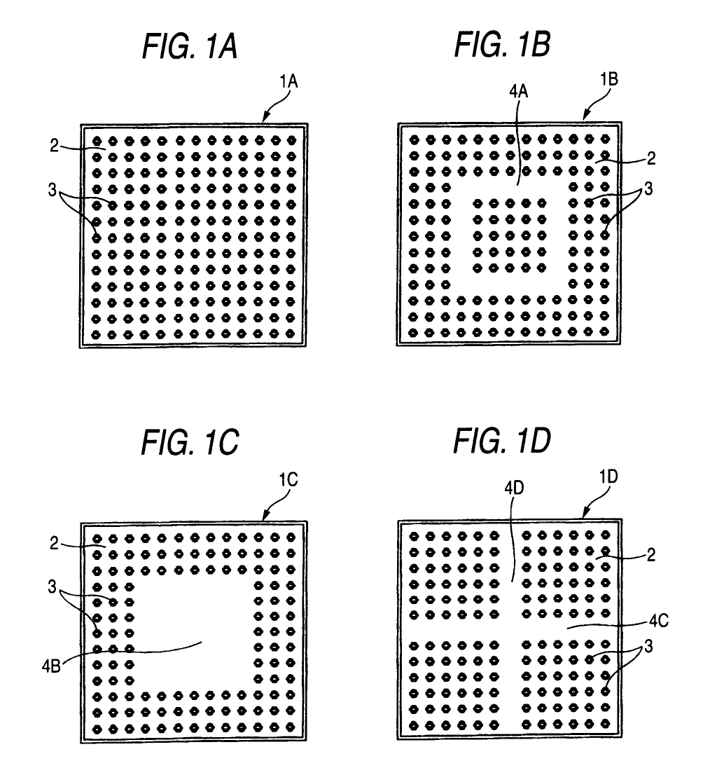

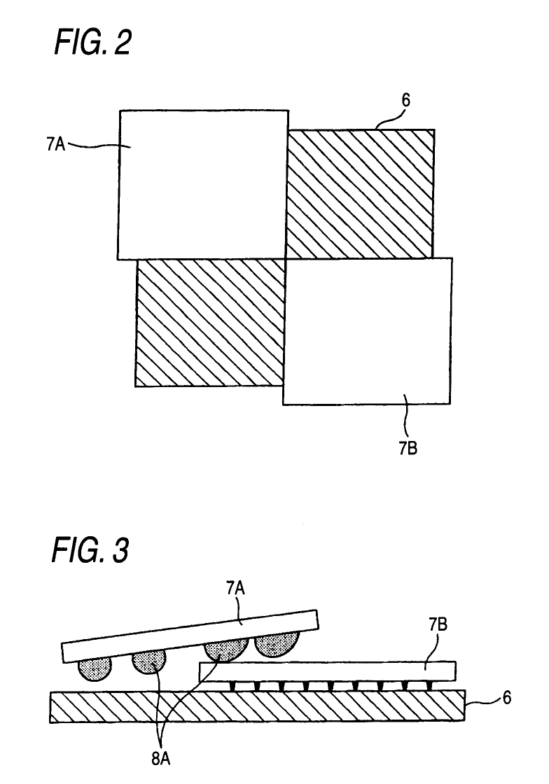

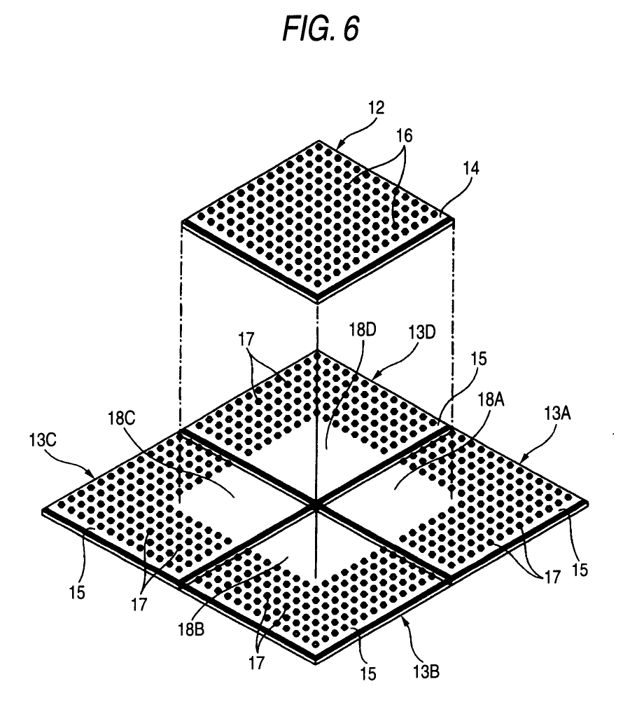

As shown in FIG. 6, the first semiconductor chip 12 is configured such that a plurality of first bumps 16 are provided in a grid pattern on a front face 14 (a first front face). When mounted on the board 11, the first semiconductor chip 12 is located at a lower layer. Moreover, the first semiconductor chip 12 has the same structure as that of the semiconductor chip 1A shown in FIG. 1A.

The second semiconductor chips 13A to 13D are mounted on the board 11 while being stacked on the first semiconductor chip 12. The second semiconductor chips 13A to 13D have the same structure where a plurality of second bumps 17 are provided on each of front faces 15 (second front faces). Moreover, the front faces 15 of the respective second semiconductor chips 13A to 13D are the same as that of the front face 14 of the first semiconductor chip 12. In the present embodiment, the respective front faces 14 and 15 of the first semiconductor chip 12 and the second semiconductor chips 13A to 13D are square shapes.

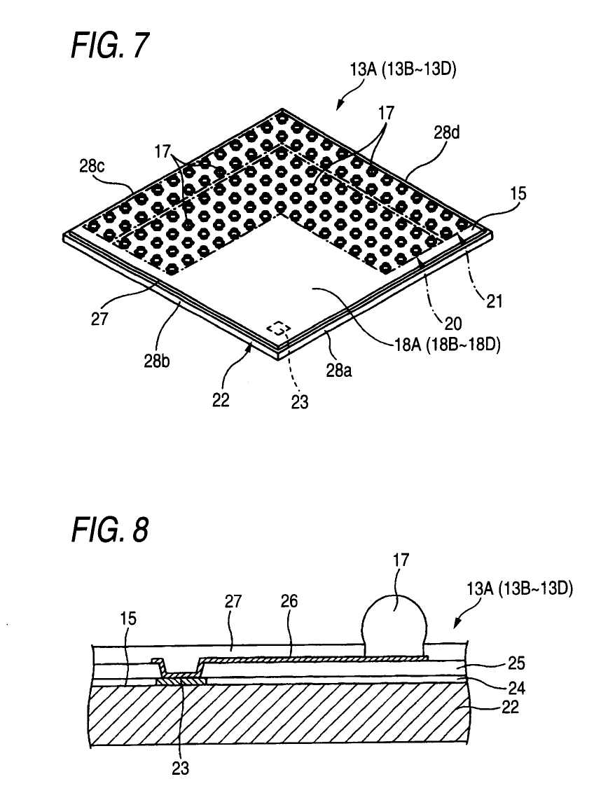

FIG. 7 is an enlarged perspective view of the second semiconductor chip 13A. As mentioned above, the respective second semiconductor chips 13A to 13D have the same structure. Accordingly, the structure of the second semiconductor chip 13A will be described hereinafter, and descriptions about the second semiconductor chips 13B to 13D are omitted.

As mentioned above, the second semiconductor chip 13A is configured such that the plurality of second bumps 17 are provided on the front face 15. However, a region where the second bumps 17 are not provided (hereinafter called “a contact region 18A (18B to 18D)”) is formed in a portion of the front face 15. In the present embodiment, the shape of the contact region 18A is a square shape, and an area of the contact region 18A account for 25% of the entire area of the front face 15.

The contact region 18A includes the outer periphery of the front face 15. Specifically, two sides of four outer peripheral sides of the contact region 18A correspond to outer edges 28a and 28b of four outer edges 28a to 28d of the front face 15. Specifically, the contact region 18A includes corners of the front face 15.

The second bumps 17 are provided on the front face 15 except the contact region 18A. The second semiconductor chip 13A is electrically connected to an electrode 23 formed on a circuit formation surface of a chip main body 22. Since the electrode 23 is usually formed along an outer periphery of the chip main body 22, a method for electrically connecting the electrode 23 to the second bumps 17 poses a problem when the wide contact region 18A is formed as in the present embodiment.

However, the second semiconductor chip 13A of the present embodiment is configured so as to electrically connect the electrode 23 to the second bumps 17, which are separated from each other, by providing a rewiring 26. This configuration will be described with reference to FIG. 8.

FIG. 8 shows a structure in which one of the plurality of second bumps 17 is connected to the electrode 23 formed on the chip main body 22 by use of the rewiring 26. The chip main body 22 is formed by dividing a wafer into pieces, for example. In the drawing, an upper surface of the chip main body 22 is taken as a circuit formation surface (the circuit formation surface is referred to as the “front face 15” in FIG. 8) where circuits are formed.

A passivation film 24 such as a nitride film is formed on the upper surface of the chip main body 22. The passivation film 24 is removed from only the position where the electrode 23 is formed, whereupon the electrode 23 is exposed from the passivation film 24. An insulation film 25 such as a polyimide film is formed on the passivation film 24. A through hole is formed in a position on the insulation film 25 opposing the electrode 23.

The rewiring 26 is formed in the form of a pattern on the insulation film 25. Specifically, a copper film is formed on the insulation film 25 by electrolytic plating technique or the electroless plating technique. At this time, the copper film is formed in the through hole, as well, to thus be connected to the electrode 23. Subsequently, a resist having a certain pattern is formed on the copper film, and then the copper film is etched while the resist as a mask, thereby forming the rewiring 26 having a given pattern.

Next, a molding resin 27 is formed on the passivation film 24 where the rewiring 26 is formed, and an opening is formed at positions on the molding resin 27 where the second bumps 17 are to be provided. The second bumps 17 are connected to the rewiring 26 by way of the openings. When the second bumps 17 are connected to the rewiring 26, copper poles (embedded in the molding resin 27 with leading ends of the poles being left) may be formed in the rewiring 26 and then the second bumps 17 may be provided at the leading ends of the copper poles.

The rewiring 26 formed as mentioned above can be formed into any shape by a resist pattern. Accordingly, even when the electrode 23 is present at a position indicated by broken lines in FIG. 7, the pattern of the rewiring 26 can be pulled outside of the contact region 18A, and the second bumps 17 can be provided outside of the contact region 18A. Thereby, even when the contact region 18A is formed in the front face 15, no problem will arise in an electrical connection between the electrode 23 and the second bumps 17.

In the meantime, the plurality of electrodes 23 formed on the front face 15 of the board 11 include signal electrodes and power/ground electrodes. As mentioned above, the positions where the second bumps 17 are to be provided can be set with a degree of flexibility, by means of the rewiring 26, with respect to the positions where the electrodes 23 are to be formed. Therefore, in the present embodiment, a region 20 where the second bumps 17 for signals, among the plurality of second bumps 17 arranged as a whole in almost L-shaped pattern, are to be provided (hereinafter called a “signal bump arrangement region 20”) is formed near the contact region 18A. A region 21 where the second bumps 17 for power/ground are to be provided (hereinafter called a “power/ground bump arrangement region 21”) is formed outside the signal bump arrangement region 20.

The stacked structure of the first semiconductor chip 12 and the multilayer structure of the second semiconductor chips 13A to 13D in the semiconductor device 10 of the present embodiment will be described hereinafter.

In order to mount the first semiconductor chip 12 and the second semiconductor chips 13A to 13D on the board 11, the four second semiconductor chips 13A to 13D are combined such that the contact regions 18A to 18D come to the center as shown in FIG. 6. As mentioned above, the first semiconductor chip 12 and the respective second semiconductor chips 13A to 13D have the same shape, and the areas of the contact regions 18A to 18D account for 25% of the areas of the respective second semiconductor chips 13A to 13D. Two side of the four outer peripheral sides of the position where the contact regions 18A to 18D are formed correspond to the outer edges 28a and 28b of the front face 15 (i.e., each of the contact regions 18A to 18D includes the corners of the front face 15).

Therefore, since the four second semiconductor chips 13A to 13D are combined together such that the contact regions 18A to 18D come to the center, the entire geometry of the contact regions 18A to 18D becomes identical with the shape of the first semiconductor chip 12. The first semiconductor chip 12 is mounted on the board 11 such that the back face (a face opposite to the front face 14) contacts the contact regions 18A to 18D.

As shown in FIG. 5, when the first semiconductor chip 12 and the second semiconductor chips 13A to 13D are mounted on the board 11, the back face of the first semiconductor chip 12 contacts the contact regions 18A to 18D. Specifically, in the contact regions 18A to 18D, the first semiconductor chip 12 is mounted on the second semiconductor chips 13A to 13D.

Since the contact regions 18A to 18D are provided on the front face 15 where the second bumps 17 are formed, the first bumps 16 and the second bumps 17 are arranged on the same side while the second semiconductor chips 13A to 13D are stacked on the first semiconductor chip 12. Specifically, all of the first bumps 16 and the second bumps 17 are allowed to oppose the board 11. Thereby, the first semiconductor chip 12 and the second semiconductor chips 13A to 13D can be flip-chip bonded to the board 11.

The second bumps 17 on the second semiconductor chips 13A to 13D are made larger in diameter than the first bumps 16 on the first semiconductor chip 12. Therefore, even when the second semiconductor chips 13A to 13D are stacked on the first semiconductor chip 12, the second semiconductor chips 13A to 13D can be reliably connected to the board 11.

According to the semiconductor device 10 of the embodiment, five semiconductor chips including semiconductor chips 12 and 13A to 13D having the same area are mounted on the board 11. At this time, on the assumption that the respective semiconductor chips 12 and 13A to 13D (an area of each of the semiconductor chips is taken as “S”) are two-dimensionally mounted on the board 11, the board 11 requires at least an area of 5×S.

In contrast, since the second semiconductor chips 13A to 13D are mounted on the first semiconductor chip 12 in the present embodiment, the area of the board 11 can be set to 4×S, and the area of the board 11 can be reduced by an area equivalent to the area of one semiconductor chip. Therefore, an attempt can be made to miniaturize the semiconductor device 10. In the semiconductor device 10 of the present embodiment, there is no necessity for ensuring, in the semiconductor device, a region where a wire loop is to be formed. This also enables to miniaturize and downsize the semiconductor device 10.

In the meantime, when attention is paid to an electrical characteristic of the semiconductor device 10 of the present embodiment, all of the first semiconductor chip 12 and the second semiconductor chips 13A to 13D are flip-chip bonded to the board 11. Hence, impedance between the board 11 and the respective semiconductor chips 12 and 13A to 13D is reduced as compared with the case where the semiconductor chips are electrically connected by use of wires, so that an electrical characteristic can be improved. Therefore, it is possible to meet a demand for speedup of the respective semiconductor chips 12 and 13A to 13D.

Moreover, in the present embodiment, the signal bump arrangement region 20 is formed near the contact region 18A, and the power/ground bump arrangement region 21 is formed outside of the signal bump arrangement region 20 (see FIG. 7). With the configuration, a signal electrode of the first semiconductor chip 12 and signal electrodes of the second semiconductor chips 13A to 13D can be connected together at a short distance by way of the board 11. Therefore, an attempt can be made to enhance an electrical characteristic between the first semiconductor chip 12 and the second semiconductor chips 13A to 13D and to realize the speedup of the chips.

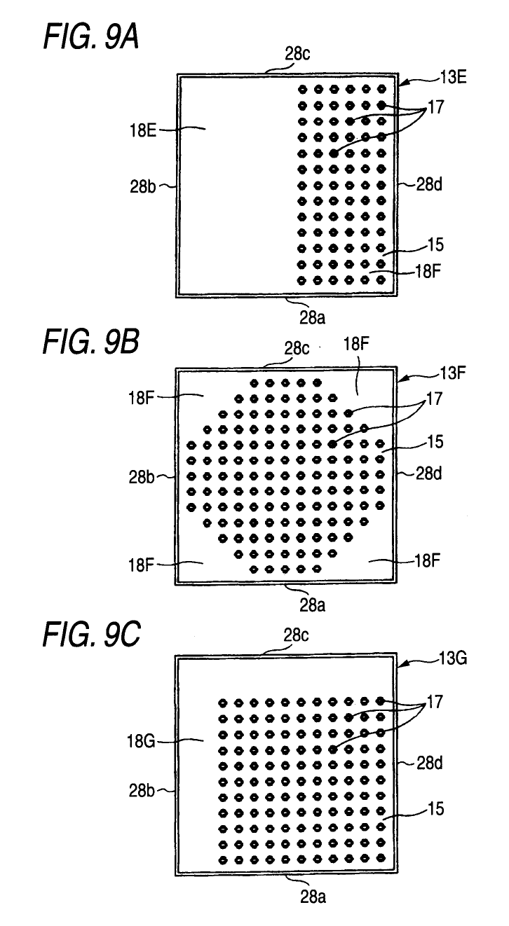

FIGS. 9A to 9C show second semiconductor chips 13E to 13G according to another embodiment of the second semiconductor chips 13A to 13D. In FIG. 9, the configurations corresponding to those shown in FIGS. 4 through 8 are assigned the same reference numerals, and explanations of their differences are omitted.

The respective second semiconductor chips 13E to 13G shown in FIGS. 9A to 9C are configured such that contact regions 18E to 18G adjoin the outer peripheries of the front face 15. The respective second semiconductor chips 13E to 13G have the same configuration in that two sides of the four outer sides of the second semiconductor chip correspond to the outer edges 28a and 28b of the four outer edges 28a to 28d of the front face 15. Therefore, the contact regions 18E to 18G of the respective second semiconductor chips 13E to 13G include the corners of the front face 15.

The second semiconductor chip 13E shown in FIG. 9A is characterized in that the contact region 18E is formed into a rectangular shape and the area of the contact region 18E accounts for 50% of the area of the front face 15. According to exemplary embodiments, when the area of the contact region 18E exceeds 50% of the area of the front face 15, difficulty was encountered in routing the rewiring 26 and achieving stability of the second semiconductor chip 13E during mounting. When the areas of the contact regions 18A to 18D account for less than 25% of the area of the front face 15, a decrease arises in mounting efficiency, and thus it is very hard to downsize the semiconductor device 10 effectively. Therefore, it is advantageous that the areas of the contact regions 18A to 18G account for 25% to 50% of the area of the front face 15.

In a second semiconductor chip 13F shown in FIG. 9B, the shape of contact regions 18F is formed into a triangular shape. In a second semiconductor chip 13G shown in FIG. 9C, a contact region 18G is formed into an L-shape. According to the present invention, the shape of the contact region is not limited to exemplary embodiments, and various shapes can be adopted within the previously-described conditions.

While the present invention has been shown and described with reference to certain exemplary embodiments thereof, it will be understood by those skilled in the art that various changes in form and details may be made therein without departing from the spirit and scope of the invention as defined by the appended claims. It is aimed, therefore, to cover in the appended claim all such changes and modifications as fall within the true spirit and scope of the present invention.

What is claimed is:

1. A semiconductor device comprising:
a board;
a first semiconductor chip having a first front face, a first back face, and first external connection terminals provided on the first front face, the first semiconductor chip being mounted on the board via the first external connection terminals by flip-chip bonding; and
a second semiconductor chip having a second front face, a second back face, and second external connection terminals and being mounted on the first semiconductor chip, the second front face having a contact region contacting the first back face of the first semiconductor chip, the second external connection terminals being provided on the second front face except the contact region, the second semiconductor chip being mounted on the board via the second external connection terminals by flip-chip bonding.

2. The semiconductor device according to claim 1, wherein an area of the contact region accounts for 25% to 50% of an area of the second front face.

3. The semiconductor device according to claim 1, wherein the second external connection includes a signal external terminal and a power/ground external terminal,
wherein the signal external connection terminal is provided near the contact region, and
wherein the power/ground external terminal is provided outside the signal external connection terminal.

4. The semiconductor device according to claim 1, wherein the contact region is formed into a rectangular shape or a triangular shape, and at least two sides of outer peripheral sides of the contact region correspond to outer edges of the second front face.

5. The semiconductor device according to claim 1, wherein the first semiconductor chip and the second semiconductor chip are formed into the same shape.

6. A semiconductor device comprising:
a board;
a first semiconductor chip having a first front face, a first back face, and first external connection terminals provided on the first front face, the first semiconductor chip being mounted on the board via the first external connection terminals by flip-chip bonding; and
four second semiconductor chips each having a second front face, a second back face, and second external connection terminals and being mounted on the first semiconductor chip, the second front face having a contact region contacting the first back face of the first semiconductor chip, the second external connection terminals being provided on the second front face except the contact region, the second semiconductor chip being mounted on the board via the second external connection terminals by flip-chip bonding,
wherein each of the contact regions accounts for 25% of the second front face.

7. A method of manufacturing a semiconductor device, the method comprising the successive steps of:
(a) providing a board;
(b) mounting a first semiconductor chip on which first external connection terminals are provided, on the board via the first external connection terminals by flip-chip bonding; and
(c) mounting a second semiconductor chip on which second external connection terminals are provided, on the board via the second external connection terminals by flip-chip bonding, while the second semiconductor chip being directly mounted on the first semiconductor chip.
